(19) United States
(12) Patent Application Publication
(10) Pub. No.: US 2014/0185381 A1
(43) Pub. Date: Jul. 3, 2014

(54) SEMICONDUCTOR APPARATUS AND METHOD OF OPERATING THE SAME

(71) Applicant: SK HYNIX INC., Icheon-si Gyeonggi-do (KR)

(72) Inventor: Nam Jae LEE, Cheongju-si Chungcheongbuk-do (KR)

(73) Assignee: SK HYNIX INC., Icheon-si Gyeonggi-do (KR)

(21) Appl. No.: 13/846,873

(22) Filed: Mar. 18, 2013

(30) Foreign Application Priority Data
Jan. 2, 2013 (KR) 10-2013-0000209

(51) Int. Cl. G11C 16/34; G11C 16/10

(52) U.S. Cl. CPC G11C 16/3459; G11C 16/10
USPC 365/185.11; 365/185.22; 365/185.18

(57) ABSTRACT

A method of operating a semiconductor device includes: performing a program operation of selected memory cells of a memory block; setting a level of a program verification voltage according to the number of times program/erase operation is performed on the selected memory cells; and performing a program verification operation by applying the program verification voltage of the set level to the selected memory cells, in which the level of the program verification voltage is increased in proportion to the number of times a program/erase operation is performed.

### CROSS-REFERENCE TO RELATED APPLICATION

This application is based on and claims priority from Korean Patent Application No. 10-2013-0000209, filed on Jan. 2, 2013, with the Korean Intellectual Property Office, the disclosure of which is incorporated herein in its entirety by reference.

### BACKGROUND

1. Technical Field

The present invention generally relates to a semiconductor device and a method of operating the same, and more particularly, to a semiconductor device in/from which data can be input/output, and a method of operating the semiconductor device.

2. Related Art

A semiconductor device for storing data may include a volatile memory device and a nonvolatile memory device. A flash memory device is representative of a nonvolatile memory device, in which a threshold voltage of a memory cell is changed according to the stored data. For example, in the method of a Single Level Cell (SLC) method of storing data of one bit in one memory cell, the threshold voltage of memory cells are divided into an erase level and a program level according to the stored data. Further, in a Multi Level Cell (MLC) method of storing data of two bits in one memory cell, the threshold voltages of memory cells are divided into an erase level and first to third program levels according to stored data.

When electrons are injected to a floating gate for a program operation for storing data, a threshold voltage of a memory cell is increased. However, when the electrons injected to the floating gate are discharged, the threshold voltage of the memory cell is decreased. Further, since the electrons injected to the floating gate of the memory cell escape from the floating gate, the threshold voltage of the memory cell may be lowered. When the threshold voltage is lowered, the data stored in the memory cell is changed, and as a result, an error is generated, thereby degrading an electrical characteristic and reliability.

### SUMMARY

The present embodiments are provided to generally provide a semiconductor device capable of improving an electrical characteristic and reliability, and a method of operating the semiconductor device.

An embodiment of the present invention provides a method of operating a semiconductor device, includes performing a program operation on selected memory cells of a memory block; storing the number of times a program/erase operation is performed with the selected memory cells; and reading the stored number of times a program/erase operation is performed before setting a level of a program verification voltage to be used in a program verification operation.

An embodiment of the present invention provides a method of operating a semiconductor device, including: performing a program operation of selected memory cells of a memory block; setting a level of a program verification voltage according to the number of times a program/erase operation is performed on the selected memory cells; and performing a program verification operation by applying the program verification voltage of the set level to the selected memory cells, in which the level of the program verification voltage is increased in proportion to the number of times a program/erase operation is performed.

An embodiment of the present invention provides a method of operating a semiconductor device, including: performing an LSB program loop of memory cells; setting an operation condition according to the number of times a program/erase operation is performed on the memory cells; and performing an MSB program loop of the memory cells according to the operation condition, in which intervals of threshold voltage distributions of the memory cells are determined according to the operation condition.

An embodiment of the present invention provides a semiconductor device, including: a memory array including a plurality of memory blocks; and a peripheral circuit configured to increase a program verification voltage or adjust intervals between threshold voltage distributions of selected memory cells in proportion to the number of times a program/erase operation is performed on the selected memory cells when a program loop of the selected memory cells in the memory block of the memory array is performed.

According to the embodiments of the present invention, it is possible to improve an electrical characteristic and reliability.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and advantages of the present invention will become more apparent to those of ordinary skill in the art by describing in detail embodiments thereof with reference to the attached drawings in which:

FIG. 1 is a block diagram for describing a semiconductor device according to an embodiment of the present invention;

FIG. 2 is a circuit diagram for describing a memory array illustrated in FIG. 1;

FIG. 3 is a distribution diagram for describing a variation of threshold voltages according to the number of times a program/erase operation is performed;

FIGS. 4A and 4B are flowcharts for describing a method of operating a semiconductor device according to an embodiment of the present invention;

FIGS. 5A and 5C are distribution diagrams for describing a method of operating a semiconductor device according to an embodiment of the present invention;

FIG. 6 is a distribution diagram for describing a method of operating a semiconductor device according to an embodiment of the present invention;

FIG. 7 is a block diagram schematically illustrating a memory system according to an embodiment of the present invention;

FIG. 8 is a block diagram schematically illustrating a fusion memory device or a fusion memory system for performing a program operation according to the aforementioned various embodiments; and

FIG. 9 is a block diagram schematically illustrating a computing system including a flash memory device according to an embodiment of the present invention.

### DETAILED DESCRIPTION

Hereinafter, an embodiment of the present invention will be described with reference to the accompanying drawings in detail. However, the present invention is not limited to an embodiment disclosed below and may be implemented in various forms and the scope of the present invention is not limited to the following embodiments. Rather, the embodiment is provided to more sincerely and fully disclose the present invention and to completely transfer the spirit of the present invention to those skilled in the art to which the present invention pertains, and the scope of the present invention should be understood by the claims of the present invention.

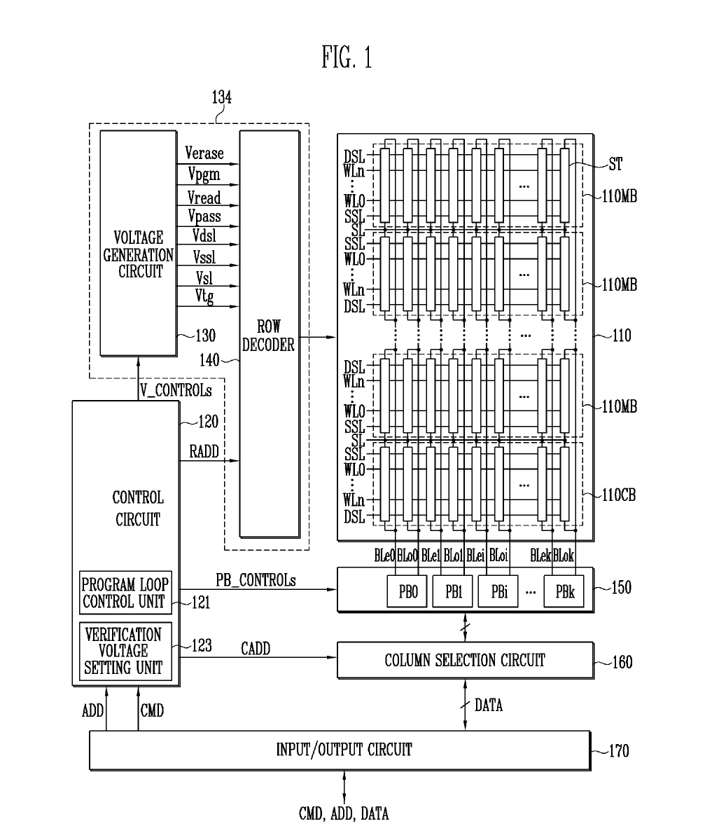

FIG. 1 is a block diagram for describing a semiconductor device according to an embodiment of the present invention.

Referring to FIG. 1, the semiconductor device may include a memory array 110 and peripheral circuits 120 to 170. The peripheral circuits include a control circuit and operation circuits 134, and 150 to 170.

The memory array 110 may include a plurality of memory blocks 110MB and a cam block 110CB. The memory block 110MB and the cam block 110CB may have the same structure. The memory block 110MB may be used for storing data input from the outside, and the cam block 110CM may be used for storing set conditions or other information (for example, the number of times a program/erase operation is performed, a defective column address, a defective block address, and the like) in relation to a data input/output operation. When a power source starts to be supplied, the information stored in the cam block 110CM may be read by the operation circuits 134, and 150 to 170 to be transmitted to the control circuit 120, and the control circuit 120 may control the operation circuits 134, and 150 to 170 so as to perform the data input/output operation of the memory cells under a predetermined condition according to the read information.

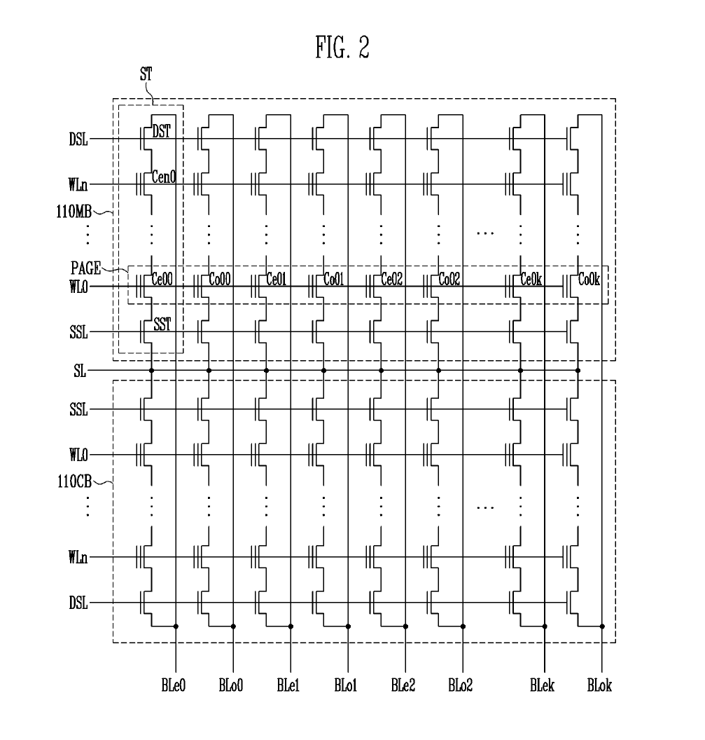

FIG. 2 is a circuit diagram for describing the memory array illustrated in FIG. 1.

Referring to FIG. 2 and FIG. 1, each memory block may include a plurality of memory strings ST connected between bit lines BLe0 to BLek, and BLo0 to BLok and a common source line SL. That is, the memory strings ST are connected to the corresponding bit lines BLe0 to BLek, and BLo0 to BLok, respectively, and are commonly connected with the common source line SL. Each memory string ST may include a source select transistor SST in which a source may be connected to the common source line SL, a cell string in which a plurality of memory cells Ce00 to Cen0 may be connected in series, and a drain select transistor DST in which a drain may be connected to the bit line BLe0. The memory cells Ce00 to Cen0 included in the cell string are serially connected between the select transistors SST and DST. A gate of the source select transistor SST may be connected to a source select line SSL, gates of the memory cells Ce00 to Cen0 are connected to word lines WL0 to WLn, respectively, and a gate of the drain select transistor DST may be connected to a drain select line DSL.

Here, the drain select transistor DST controls the connection or blocking between the cell strings Ce00 to Cen0 and the bit line, and the source select transistor SST controls the connection or blocking between the cell strings Ce00 to Cen0 and the common source line SL.

The memory cells included in the memory cell block in the NAND flash memory device may be divided in the unit of a physical page or a logical page. For example, memory cells Ce00 to Ce0k, and Co00 to Co0k connected to one word line (for example, the word line WL0) configures one physical page PAGE. Further, even numbered memory cells Ce00 to Ce0k connected to one word line (for example, the word line WL0) configure one even physical page, and odd numbered memory cells Co00 to Co0k configure one odd physical page. The page (or the even page and the odd page) serves as a basic unit of the program operation or the read operation.

Referring to FIG. 1 again, the peripheral circuits 120, 134, and 150 to 170 are configured to perform a program loop, an erase loop, and a read operation of the memory cells Ce00 to Ce0k or Co00 to Co0k connected to the selected word line (for example, the word line WL0). The peripheral circuit may include the control circuit 120 for controlling the program loop, the erase loop, and the read operation and the operation circuits 134, and 150 to 170 configured to perform the program loop, the erase loop, and the read operation under the control of the control circuit 120. In order to perform the program loop, the erase loop, and the read operation, the operation circuits 134, and 150 to 170 are configured to selectively output operation voltages Verase, Vpgm, Vread, Vpass, Vdsl, Vssl, and Vsl to the local lines SSL, WL0 to WLn, and DSL of the selected memory block and the common source line SL, and control precharge/discharge of the bit lines BLe0 to BLek or BLo0 to BLok or sense current flow of the bit line BL0 to BLk or BLo0 to BLok. Especially, the operation circuits 134, and 150 to 170 may be configured to as to perform the read operation of the selected memory cells connected to the selected word line by using first to n^{th} level read voltages.

In a case of the NAND flash memory device, the operation circuits include a voltage supply circuit 134, a read/write circuit 150, a column selection circuit 160, and an input/output circuit 170. Each constituent element will be described in detail below.

The control circuit 120 outputs a voltage control signal V_CONTROLs for controlling the voltage supply circuit 130 so that the operation voltages Verase, Vpgm, Vread, Vpass, Vdsl, Vssl, and Vsl for performing the program loop, the erase loop, and the read operation are generated with desired levels in response to a command signal CMD input through the input/output circuit 170. Further, the control circuit 120 outputs control signals PB_CONTROLs for controlling circuits PB0 to PBk included in the read/write circuit 150 in order to perform the program loop, the erase loop, and the read operation. Further, when an address signal ADD is input in the control circuit 120, a column address signal CADD and a row address signal RADD are generated by the input address signal ADD and output from the control circuit 120.

Especially, the control circuit 120 may include a program loop control unit 121 for controlling the program loop, and a verification voltage setting unit 123 for adjusting a program verification voltage applied to the memory cells to the number of times a program/erase operation is performed when a program verification operation is performed.

The voltage supply circuit 134 generates the necessary operation voltages Verase, Vpgm, Vread, Vpass, Vdsl, Vssl, and Vsl according to the program loop, the erase loop, and the read operation of the memory cells, and outputs the operation voltages to the local lines SSL, and WL0 to WLn, DSL and the common source line SL of the selected memory block in response to the row address signal RADD of the control circuit 120.

Especially, the voltage supply circuit 134 may output the program verification voltage used for the program verification operation in the program loop by the Single Level Cell (SLC) method with various levels. Further, the voltage supply circuit 134 output first to third program verification voltages used for the program verification operation after an MSB program operation in the program loop in the Multi Level Cell (MLC) method with various levels, respectively. Here, each of the first to third program verification voltages may be changed according to the number of times a program/erase operation is performed. Detailed contents will be described below.

The voltage supply circuit 134 may include the voltage generation circuit 130 and the row decoder 140. The voltage generation circuit 130 generates the operation voltages Verase, Vpgm, Vread, Vpass, Vdsl, Vssl, and Vsl in response to the voltage control signal V_CONTROLs, and the row decoder 140 transmits the operation voltages to the local lines SSL, WL0 to WLn, and DSL of the selected memory block among the memory blocks 110 MB and the common source line SL in response to the row address signal RADD.

As described above, the operation voltages Verase, Vpgm, Vread, Vpass, Vdsl, Vssl, and Vsl described below are output and changed by the voltage supply circuit 130 according to the voltage control signal V_CONTROLs.

The read/write circuit 150 may include each of a plurality of page buffers connected with the memory array 110 through the bit lines BLe0 to BLek, and BLo0 to BLok. When the program operation is performed, the page buffers PB0 to PBk selectively precharge the bit lines BLe0 to BLek, and BLo0 to BLok according to a PB control signal PB_CONTROLs and data DATA to be stored in the memory cells. When the program verification operation or the read operation is performed, the page buffers PB0 to PBk precharge the bit lines BLe0 to BLek or BLo0 to BLok according to the PB control signal PB_CONTROLs of the control circuit 120, and then latches data read from the memory cell by sensing a voltage change or current of the bit lines BLe0 to BLek or BLo0 to BLok.

Especially, when a external power source starts to be supplied, the read/write circuit 150 reads information stored in the cam cells of the cam block 110CM according to the control of the control circuit 120, and the read information is stored in the control circuit 120. When the program verification operation is performed, the verification voltage setting unit 123 controls a level of the program verification voltage according to the number of times a program/erase operation, read from the cam block 110CM, is performed.

The column selection circuit 160 selects the page buffers PB0 to PBk included in the page buffer group 150 in response to the column address CADD output from the control circuit 120. That is, the column selection circuit 160 sequentially transmits data to be stored in the memory cells to the page buffers PB0 to PBk in response to the column address CADD. Further, the column selection circuit 160 sequentially selects the page buffers PB0 to PBk in response to the column address CADD so as to output the data of the memory cells latched in the page buffers PB0 to PBk to the outside by the read operation.

The input/output circuit 170 transmits the command signal CMD and the address signal ADD input from the outside to the control circuit 120. Further, the input/output circuit 170 transmits data DATA input from the outside to the column selection circuit 160 when the program operation is performed, or performs an operation of outputting the data read from the memory cells to the outside when the read operation is performed.

FIG. 3 is a distribution diagram for describing a variation of the threshold voltages according to the number of times a program/erase operation is performed. The y-axis indicating the number of cells and the x-axis indicating the voltage V.

Referring to FIG. 3, when a Least Significant Bit (LSB) program loop and a Most Significant Bit (MSB) program loop for storing data in the MLC method are completed, the threshold voltage of the memory cells are distributed at an erase level (not shown), and three program levels (PV1 to PV3). When the number of program/erase operations are low, the threshold voltages are maintained at a high level A, but as the number of program/erase operations are increased, the threshold voltages (i.e., A, B, C, D, and E) are changed to a lower level E. That is, when the number of times of program/erase operation is gradually increased, the amount of electrons discharged from the floating gate is increased, so that a variation of the threshold voltage is increased. Accordingly, the data stored in the memory cell may be changed.

Accordingly, the program loop control unit 121 and the verification voltage setting unit 123 of the control circuit 120 controls the operation circuits 134, 150, and 160 in order to change the program verification voltage according to the number of times a program/erase operation is performed or the increase in intervals between the threshold voltage distributions PV1, PV2, and PV3, so that it is possible to prevent the data stored in the memory cell from being changed even though the threshold voltage is lowered. This will be described in detail below. Hereinafter, a method of operating the semiconductor device will be described in detail.

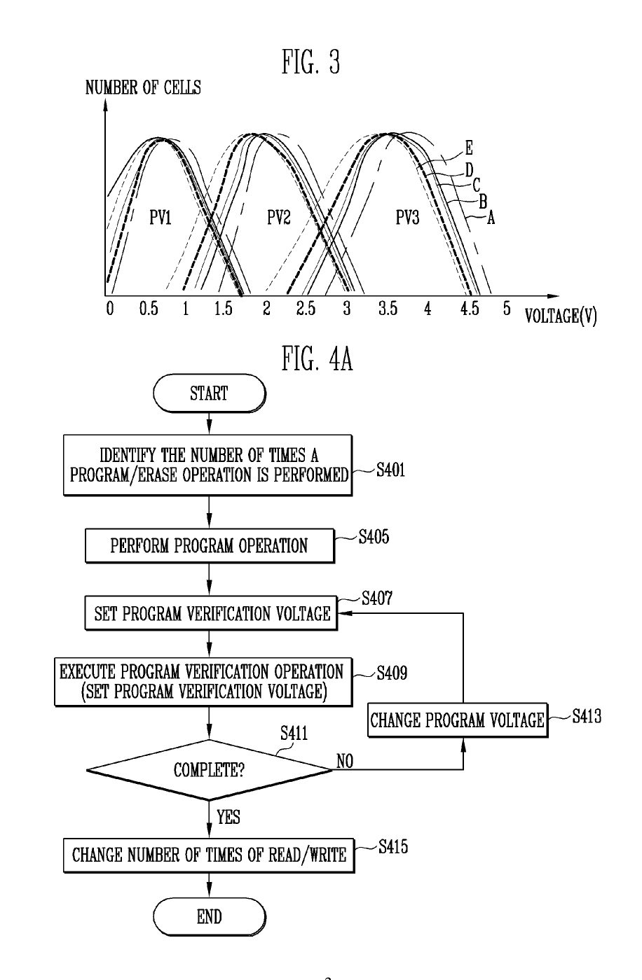

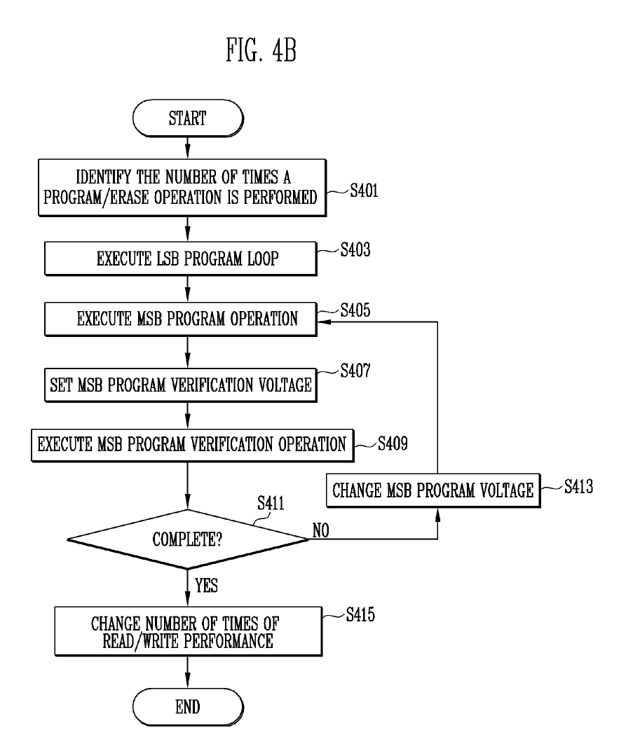

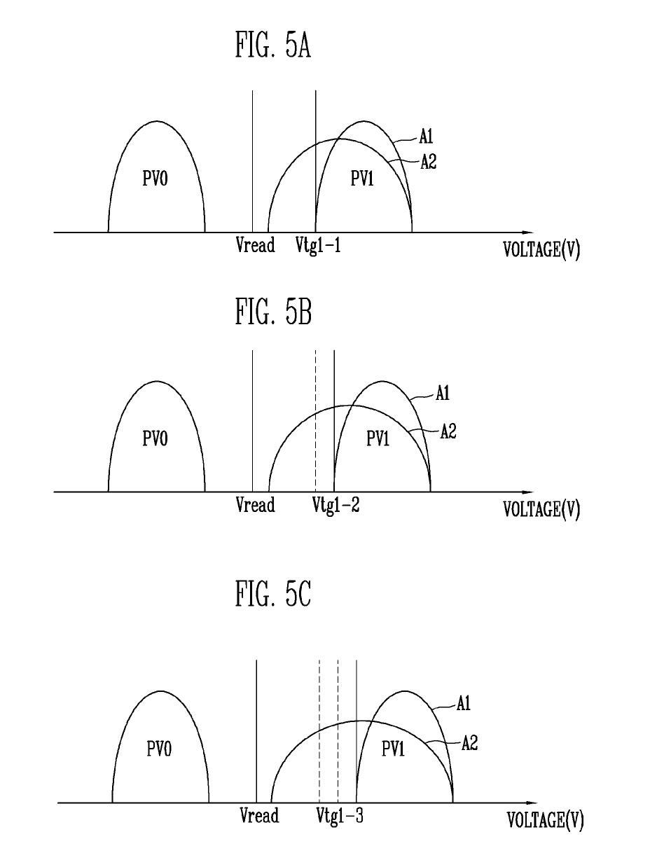

FIGS. 4A and 4B are flowcharts for describing a method of operating the semiconductor device according to the embodiments of the present invention, and FIGS. 5A and 5B are distribution diagrams for describing the method of operating the semiconductor device according to the embodiments of the present invention.

FIGS. 1 and 4A refer to the number of times a program/erase operation is performed on the memory cells (or memory block) on which the program loop is to be executed for step S401. This will be described in detail below.

First, when an external power source is supplied in a power-off state, the operation circuits 134, 150, and 160 read predetermined conditions related to a data input/output operation or other information, such as the number of times a program/erase operation is performed, a defective column address, and a defective block address, from the cam cells of the cam block 110CM according to the control of the control circuit 120, and the control circuit 120 stores the read information in an internal register (not shown). Here, the number of times of a program/erase operation performance may include the total number of times a program/erase operation has been performed starting from the completion of the manufacturing of the semiconductor device to the present.

In steps S405 to S413, the operation circuits 134, 150, and 160 perform the program loop for storing data in the selected memory cells of the memory block 110 MB according to the control of the program loop control unit 121 included in the control circuit 120.

First, in step S405, the operation circuits 134, 150, and 160 perform the program operation for storing the data in the selected memory cells. For example, the operation circuits 134, 150, and 160 apply a program inhibition voltage (for example, a power source voltage) to the bit lines of the memory cells in which data “1” is stored, and apply a program allowance voltage (for example, a ground voltage) to the bit lines of the memory cells in which data “0” is stored. Next, the operation circuits 134, 150, and 160 apply the program voltage Vpgm to the selected word line, and apply a pass voltage Vpass to the non-selected word lines. As a result, as illustrated in FIG. 5A, the threshold voltages of the memory cells in which data “1” is stored maintain the erase level PV0, and the threshold voltages of the memory cells in which data “0” is stored are increased to the program level PV1.

In step S407 (i.e., SET PROBRAM VERIFICATION VOLTAGE), the verification voltage setting unit 123 of the control circuit 120 sets a level of a verification voltage to be used in the program verification operation according to the number of times a program/erase operation is performed. For example, when the number of times a program/erase operation is performed is equal to or smaller than 10,000, a program verification voltage Vtg1-1 may be set to the lowest first level as illustrated in FIG. 5A. When the number of times a program/erase operation is performed is larger than 10,000 and equal to or lower than 50,000, a program verification voltage Vtg1-2 may be set to a second level higher than the first level as illustrated in FIG. 5B. When the number of times a program/erase operation is performed is larger than 50,000, a program verification voltage Vtg1-3 may be set to the highest or third level. These setting ranges are for illustrative purposes only, and may be changed according to a design, and the program verification voltage may be more finely divided and set with, for example, three stages or more.

In the verification voltage setting method, when the number of program/erase operation performances are increased, the level of the program verification voltage is increased, and a difference between the read voltage Vread used in the read operation and the program verification voltages Vtg1-1, Vtg1-2, and Vtg1-3 are increased. Especially, when the level of the program verification voltage is increased, the distribution of the threshold voltage after the completion of the program loop is also increased by the increased amount of the program verification voltage. Further, when the level of the program verification voltage is increased, the intervals between the threshold voltage distributions are increased. That is, as the number of program/erase operation performances increase, the intervals between the threshold voltage distributions are increased.

In step S409, the program verification operation is performed by using the program verification voltage of the predetermined level. For example, the operation circuits 134, 150, and 160 precharge the bit lines BLe0 to BLek or BLo0 to Blok, apply the predetermined program verification voltage to the selected word line, apply the pass voltage Vpass to the non-selected word lines, and then sense a voltage change or current of the bit lines BLe0 to BLek or BLo0 to Blok.

In step S411 (i.e., COMPLETE?), when it is detected that the threshold voltages are lower than the program verification voltage according to a result of the sensing, the program loop is performed again.

When the program loop is performed again, the program voltage Vpgm is increased by a predetermined value in step S413 (i.e., CHANGE PROGRAM VOLTAGE). Next, the program loop is performed again by using the program voltage Vpgm and the set program verification voltage in steps S405 to S411.

In step S411, when it is detected that the threshold voltages are higher than the program verification voltage according to the result of the sensing, the program loop is completed.

After the completion of the program loop (i.e., YES), in order to increase the number of program/erase operation performances, the operation circuits 134, 150, and 160 may renew the number of program/erase operation performances stored in the cam block 110CB under the control of the control circuit 120 in step S415 (i.e., CHANGE NUMBER OF TIMES OF PROGRAM/ERASE). Step S415 of renewing the number of times of program/erase operation may be performed after the performance of the read operation several times and the completion of the erase loop.

In the meantime, the level of the program verification voltage is set in step S407 after the performance of the program operation and before the performance of the program verification operation, but the level of the program verification voltage may be set before the performance of the program operation.

When the number of program/erase operation performances is large, the threshold voltages of the memory cells are rapidly increased compared to a case where the number of program/erase operation performances is small under the same operating conditions. That is, when the number of program/erase operation performances is small, it takes a long time for the threshold voltage to reach a target level. Accordingly, as illustrated in FIG. 5A, when the program verification voltage Vtg1-1 is set to a low level, the target level is lowered, and the time for the threshold voltage to reach the target level (that is, the operation time) may be reduced. Further, when the number of program/erase operation performances are small and the threshold voltage is low, the amount of electrons escaping from the floating gate is not large, so that a difference between a threshold voltage distribution A1 after the completion of the program loop and a threshold voltage distribution A2 changed according to the elapse of time is not large. Accordingly, even though the time elapses, the threshold voltage distribution A2 is positioned at a level higher than that of the read voltage Vread, so that it is possible to prevent the data stored in the memory cell from being changed.

Additionally, when the number of program/erase operation performances are large, the threshold voltage is rapidly increased to the target level, so that it is preferable to set the program verification voltage Vtg1-3 to a high level as illustrated in FIG. 5C. Even though the program verification voltage Vtg1-3 is set to the high level, the threshold voltage is rapidly increased, so that the time for the threshold voltage to be increased to the target level is not increased. Further, when the number of program/erase operation performances are large, the amount of electrons discharged from the floating gate is increased, so that a difference between the threshold voltage distribution A1 after the completion of the program loop and the threshold voltage distribution A2 changed according to the elapse of time is increased. However, since the threshold voltage distribution A1 is positioned at a high level, even though the time elapses, the threshold voltage distribution A2 is positioned at a level higher than that of the read voltage Vread, so that it is possible to prevent the data stored in the memory cell from being changed.

As described above, by increasing the program verification voltage or increasing the intervals between the threshold voltage distributions PV0 and PV1 in proportion to the number of times a program/erase operation is performed, it is possible to improve the reliability by preventing the stored data from being changed even though the time elapses.

Additionally, FIG. 5B illustrates the erase level PV0 and the program level PV1, threshold voltage distributions A1 and A2, and the read voltage Vread.

The method has been described in relation to the program loop in the SLC method, but the method may be applied to the program loop in the MLC method. This will be described in detail below.

Referring to FIG. 4B, in step S401, the number of program/erase operation performances of the memory cells (or the memory block) on which the program loop is to be executed is identified. The identification of the number of times a program/erase operation is performed may be identical to the method performed in step S401 as described in FIG. 4A.

In step S403, the operation circuits 134, 150, and 160 perform the LSB program loop f

or storing the LSB data in the selected memory cells of the memory block 110 MB according to the control of the program loop control unit 121 included in the control circuit 120. When the LSB program loop is completed, as illustrated in FIG. 5A, the threshold voltages of the memory cells in which data “1” is stored as the LSB data are maintained at the erase level PV0, and the threshold voltages of the memory cells in which data “0” is stored in the LSB data is increased to a level higher than 0 V.

Then, the threshold voltages of the memory cells are changed again according to the execution of the MSB program operation or loop, so that it is not necessary to adjust an LSB program verification voltage according to the number of times a program/erase operation is performed in the process of executing the LSB program loop in step S403.

In steps S405 to S413, the operation circuits 134, 150, and 160 perform an MSB program loop for storing MSB data in the selected memory cells of the memory block 110 MB according to the control of the program loop control unit 121 included in the control circuit 120.

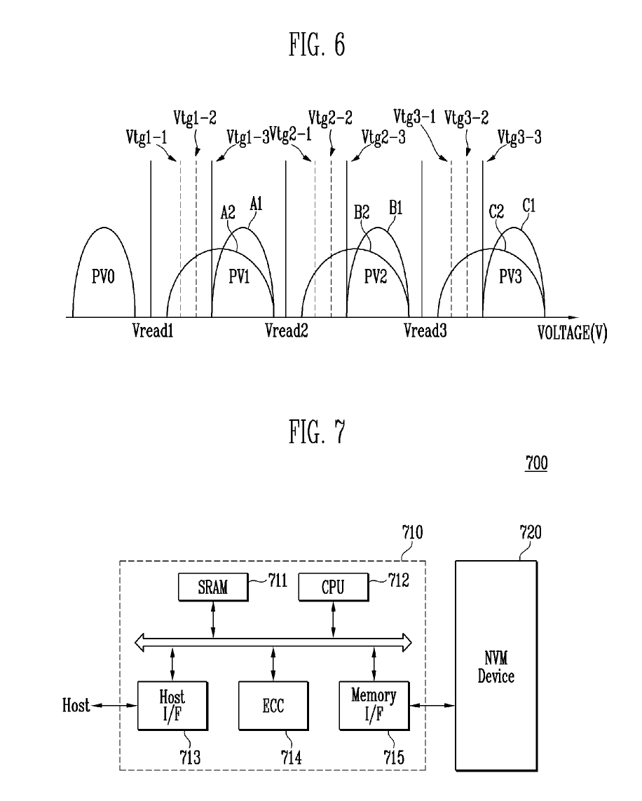

First, in step S405, the operation circuits 134, 150, and 160 perform the MSB program operation for storing MSB data in the selected memory cells. For example, the operation circuits 134, 150, and 160 apply a program inhibition voltage (for example, a power source voltage) to the bit lines of the memory cells in which data “1” is stored as the MSB data, and apply a program allowance voltage (for example, a ground voltage) to the bit lines of the memory cells in which data “0” is stored. Next, the operation circuits 134, 150, and 160 apply the program voltage Vpgm to the selected word line, and apply a pass voltage Vpass to non-selected word lines. As a result, as illustrated in FIG. 6, the threshold voltages of the memory cells in which data “1” is stored as the MSB data maintain the erase level PV0, and the threshold voltages of the memory cells in which data “1” is stored as the LSB data and data “0” is stored as the MSB data are increased to a first program level PV1 from the erase level PV0. The threshold voltages of the memory cells in which data “0” is stored as the LSB data and data “1” is stored as the MSB data are increased to the second program level PV2, and the threshold voltages of the memory cells in which data “0” is stored as the LSB data and data “0” is stored as the MSB data are increased to a third program level PV3.

In step S407 (i.e., SET MSB PROGRAM VERIFICATION VOLTAGE), the verification voltage setting unit 123 of the control circuit 120 sets first to third program verification voltages to be used in the program verification operation according to the number of times a program/erase operation is performed. For example, when the number of times a program/erase operation is performed is equal to or smaller than 10,000, the first to third program verification voltages Vtg1-1, Vtg2-1, and Vtg3-1 may be set to the lowest levels within the respective predetermined ranges. When the number of program/erase operation performances are equal to or lower than 50,000, the first to third program verification voltages Vtg1-1, Vtg2-1, and Vtg3-1 may be set to the second levels (i.e., Vtg1-2, Vtg2-2, Vtg3-2) higher than the first levels within the respective predetermined ranges. When the number of program/erase operation performances are larger than 50,000, the first to third program verification voltages Vtg1-1, Vtg2-1, and Vtg3-1 may be set to the highest third levels within the respective predetermined ranges. These setting ranges are for illustrative purposes only, and may be changed according to a design, and the first to third program verification voltages may be more finely divided and set with, for example, three stages or more.

According to the verification voltage setting method, as the number of times a program/erase operation is performed is increased, the differences between the read voltages Vread1, Vread2, and Vread3 and the program verification voltages Vtg1-3, Vtg2-3, and Vtg3-3 are increased, respectively, and the threshold voltage distributions PV1, PV2, and PV3 after the completion of the program loop are increased by the amount of the increase of the program verification voltages Vtg1-3, Vtg2-3, and Vtg3-3, respectively. Further, when the levels of the program verification voltages Vtg1-3, Vtg2-3, and Vtg3-3 are increased as the number of times a program/erase operation is performed is increased, the intervals between the threshold voltage distributions PV0 to PV3 may be increased. In step S409 (i.e., EXECUTE MSB PROGRAM VERIFICATION OPERATION), the program verification operations are performed by using the first to third program verification voltages Vtg1-1, Vtg2-1, and Vtg3-1 of the set levels, respectively. For example, the operation circuits 134, 150, and 160 precharge the bit lines BLe0 to BLek or BLo0 to Blok, apply the set program verification voltage to the selected word line, apply the pass voltage Vpass to the non-selected word lines, and then sense a voltage change or current of the bit lines BLe0 to BLek or BLo0 to Blok. The program verification operations using the first to third program verification voltages Vtg1-1, Vtg2-1, and Vtg3-1 may be sequentially performed.

In step S411 (i.e., COMPLETE?), when it is detected that the threshold voltages are lower than the program verification voltage according to a result of the sensing (i.e., NO), the MSB program loop is performed again.

When the MSB program loop is performed again, the program voltages Vpgm are increased by a predetermined value in step S413 (i.e., CHANGE MSB PROGRAM VOLTAGE). Next, the MSB program loop is performed again by using the program voltage Vpgm and the set program verification voltage in steps S405 to S411.

In step S411, when it is detected that the threshold voltages are higher than the program verification voltage according to the result of the sensing (i.e., YES), the MSB program loop is completed. That is, when the threshold voltages are normally distributed in the corresponding threshold voltage distributions PV0 to PV3 according to the data, respectively, the MSB program loop is completed.

After the completion of the MSB program loop, in order to increase the number of times a program/erase operation is performed, the operation circuits 134, 150, and 160 may renew the number of program/erase operation performances stored in the cam block 110CB under the control of the control circuit 120 in step S415. Step S415 of renewing the number of times a program/erase operations is performed may be performed after the performance of the read operation several times and the completion of the erase loop.

In the meantime, the levels of the program verification voltages are set in step S407 after the performance of the MSB program operation and before the performance of the MSB program verification operation, but the levels of the program verification voltages may be set before the performance of the MSB program operation.

When the first to third program verification voltages are set in step S407 as described above, the intervals between the threshold voltage distributions PV0 to PV3 may be increased. Accordingly, even though a difference between the threshold voltage distributions A1, B1, and C1 after the completion of the MSB program loop and the threshold voltage distributions A2, B2, and C2 changed according to the elapse of time is increased, the threshold voltage distributions A2, B2, C2 are positioned at a level higher than those of the read voltages Vread1, Vread2, and Vread3, so that it is possible to prevent the data stored in the memory cell from being changed.

FIG. 7 is a block diagram schematically illustrating a memory system according to an embodiment of the present invention.

Referring to FIG. 7, the memory system 700 according to an embodiment of the present invention may include a nonvolatile memory device 720 and a memory controller 710.

The nonvolatile memory device 720 may be formed of the aforementioned semiconductor device. The memory controller 710 is configured so as to control the nonvolatile memory device 720. The memory system 700 may be provided as a memory card or a Solid State Disk (SSD) by a combination of the nonvolatile memory device 720 with the controller 710. An SRAM 711 is used as an operation memory of a processing unit 712. A host interface 713 may include a data exchange protocol of a host connected with the memory system 700. An error correction block 714 (i.e., ECC) detects and corrects an error included in data read from the nonvolatile memory device 720. A memory interface 715 (i.e. Memory I/F) performs interfacing with the nonvolatile memory device 720 of the present invention. The processing unit 712 (i.e., CPU) performs a general control operation for data exchange of the memory controller 710.

Although it is not illustrated in the drawing, a fact that the memory system 700 according to the present invention may further provide a ROM (not illustrated) for storing code data for interfacing with the host is apparent to those skilled in the art. The nonvolatile memory device 720 may be provided as a multi-chip package formed of a plurality of flash memory chips. The aforementioned memory system 700 of the present invention may provide a storage media of high reliability with a low error generation probability. Especially, the flash memory device of the present invention may be included in a memory system, such as a semiconductor disk device (Solid State Disk (SSD)). In this case, the memory controller 710 may communicate with the outside (e.g., the host) through one of the various interface protocols, such as USB, MMC, PCI-E, SATA, PATA, SCSI, ESDI, and IDE, etc.

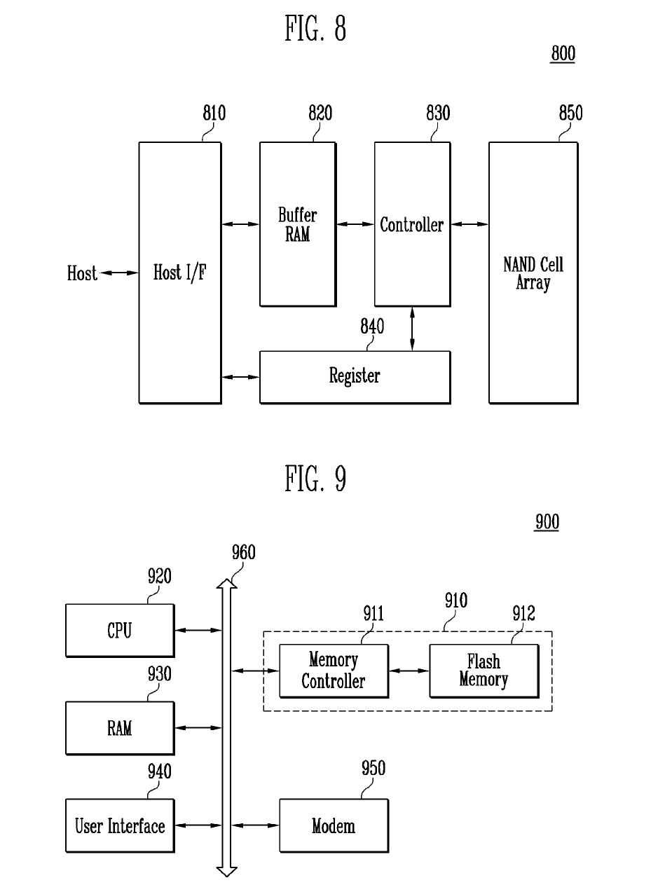

FIG. 8 is a block diagram schematically illustrating a fusion memory device or a fusion memory system for performing a program operation according to the various aforementioned embodiments. For example, the technical characteristic of the present invention may be applied to OneNAND flash memory device 800 as the fusion memory device.

The OneNAND flash memory device 800 may include a host interface 810 (i.e., Host I/F) for exchanging various information with a device (i.e., Host) using a different protocol, a buffer RAM 820 for storing a code for driving a memory device or temporarily storing data, a controller 830 for controlling reading, a program, and every state in response to a control signal and a command provided from the outside, a register 840 in which data, such as a command, an address, and configuration for defining a system operation environment inside the memory device is stored, and a NAND flash cell memory 850 (i.e., NAND Cell Array) including an operation circuit including a nonvolatile memory cell and a page buffer. The memory array illustrated in FIG. 2 is applied to the memory array of the NAND flash cell array 850.

FIG. 9 is a block diagram schematically illustrating a computing system including a flash memory device 912 according to an embodiment of the present invention.

The computing system 900 according to the present invention may include a microprocessor 920 (i.e., CPU), a RAM 930, a user interface 940, a modem 950, such as a baseband chip set, and a memory system 910, which are electrically connected to a system bus 960. When the computing system 900 according to the present invention is a mobile device, a battery (not shown) for supplying an operation voltage of the computing system 900 may be additionally provided. Although it is not illustrated in the drawing, a fact that the computing system 800 according to the present invention may further include an application chipset, a Camera Image Processor (CIS), a mobile DRAM, and the like is apparent to those skilled in the art. The memory system 910 may configure, for example, a Solid State Drive/Disk (SSD) using a nonvolatile memory for storing data. Otherwise, the memory system 910 may be provided as the fusion flash memory (for example, the OneNAND flash memory).

As described above, the embodiments have been disclosed in the drawings and the specification. The specific terms used herein are for purposes of illustration, and do not limit the scope of the present invention defined in the claims. Accordingly, those skilled in the art will appreciate that various modifications and other equivalent examples may be made without departing from the scope and spirit of the present disclosure. Therefore, the sole technical protection scope of the present invention will be defined by the technical spirit of the accompanying claims.

What is claimed is:

1. A method of operating a semiconductor device, comprising:
performing a program operation of selected memory cells of a memory block;
setting a level of a program verification voltage according to the number of times a program/erase operation is performed on the selected memory cells; and
performing a program verification operation by applying the program verification voltage of the set level to the selected memory cells,
wherein the level of the program verification voltage is increased in proportion to the number of times a program/erase operation is performed.

2. The method of claim 1, further comprising reading the number of times a program/erase operation is performed from cam cells of a cam block before performing the program operation.

3. The method of claim 1, further comprising renewing the number of times a program/erase operation is performed after completion of the program operation.

4. The method of claim 1, wherein an increase ratio of the program verification voltage is changed in proportion to the number of times a program/erase operation is performed.

5. A method of operating a semiconductor device, comprising:
performing an LSB program loop of memory cells;
setting an operation condition according to the number of times a program/erase operation is performed on the memory cells; and
performing an MSB program loop of the memory cells according to the operation condition,
wherein intervals of threshold voltage distributions of the memory cells are determined according to the operation condition.

6. The method of claim 5, further comprising reading the number of times a program/erase operations is performed from cam cells of a cam block before the performing of the MSB program loop.

7. The method of claim 5, further comprising renewing the number of program/erase operation performances after completion of the MSB program loop.

8. The method of claim 5, wherein first to third MSB program verification voltages applied to the memory cells are increased in proportion to the number of program/erase operation performances that occur in an MSB program verification operation of the MSB program loop.

9. The method of claim 8, wherein an increase ratio of the first to third MSB program verification voltages is increased in proportion to the number of times a program/erase operation is performed.

10. The method of claim 8, wherein the third MSB program verification voltage is increased more than an increase of the first MSB program verification voltage.

11. A semiconductor device, comprising:
a memory array including a plurality of memory blocks; and
a peripheral circuit configured to increase a program verification voltage or adjust intervals between threshold voltage distributions of selected memory cells in proportion to the number of times a program/erase operation is performed on the selected memory cells when a program loop of the selected memory cells in the memory block of the memory array is performed.

12. The semiconductor device of claim 11, wherein the memory array further includes a cam block, and the peripheral circuit reads the number of times a program/erase operation is performed on cam cells of the cam block before the performance of the program loop.

13. The semiconductor device of claim 12, wherein the peripheral circuit renews the number of program/erase operation performances stored in the cam cells after completion of the program loop.

14. The semiconductor device of claim 11, wherein the peripheral circuit changes an increase ratio of the program verification voltage in proportion to the number of times a program/erase operation is performed.

15. The semiconductor device of claim 12, wherein the program loop includes an LSB program loop and an MSB program loop, and the peripheral circuit reads the number of times a program/erase operation is performed from the cam cells before the performance of the MSB program loop.

16. The semiconductor device of claim 15, wherein the peripheral circuit renews the number of program/erase operation performances stored in the cam cells after completion of the MSB program loop.

17. The semiconductor device of claim 15, wherein the peripheral circuit increases first to third MSB program verification voltages applied to the memory cells in proportion to the number of times a program/erase operation is performed in an MSB program verification operation of the MSB program loop.

18. The semiconductor device of claim 17, wherein the peripheral circuit increases an increase ratio of the first to third MSB program verification voltage in proportion to the number of times a program/erase operation is performed.

19. The semiconductor device of claim 17, wherein the peripheral circuit increases the third program verification voltage more than the first program verification voltage.
